(19) United States
(12) Patent Application Publication
(10) Pub. No.: US 2009/0184357 A1
(43) Pub. Date: Jul. 23, 2009

(54) SOI BASED INTEGRATED CIRCUIT AND METHOD FOR MANUFACTURING

(75) Inventor: Dongping Wu, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/016,342

(22) Filed: Jan. 18, 2008

(51) Int. Cl. H01L 27/108; H01L 21/8242

(52) U.S. Cl. 257/303; 438/155; 257/E27.092; 257/E21.646

(57) ABSTRACT

A SOI based integrated circuit and method for manufacturing a SOI based integrated circuit is disclosed. One embodiment provides an integrated circuit having a silicon-on-insulator carrier including a substrate, a buried insulating layer on the substrate and a semiconductor layer on the buried insulating layer. A trench extends at least through the semiconductor layer and into the buried insulating layer. A conductive region is formed in the buried insulating layer, wherein the conductive region partly surrounds the trench and is configured to interconnect the semiconductor layer and the substrate.

### BACKGROUND

One or more embodiments relate to an SOI based integrated circuit, a method for manufacturing an SOI based integrated circuit, an SOI memory cell and an electronic device.

Silicon-on-insulator (SOI) based integrated circuits offer a number of advantages vis-à-vis integrated circuits based on a common silicon substrate. The SOI technique creates semiconductor devices within a thin top silicon layer that is separated from the silicon substrate by a thin insulating layer. For instance, an increase of switching speeds of semiconductor components may be achieved by reducing capacitances ascribed to space-charge regions and even a complete insulation of active areas of semiconductor devices may be realized. However, owing to the specific insulation of active areas, challenges, e.g., with regard to electrical characteristics have to be met.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic cross-sectional view of an integrated circuit according to one embodiment.

FIG. 2-4 illustrate schematic plan views of integrated circuits according one or more embodiments.

FIG. 5 illustrates a schematic cross-sectional view of an SOI DRAM memory cell according to one embodiment.

FIG. 6 illustrates a flowchart of a method for manufacturing an integrated circuit according to one embodiment.

FIG. 7 illustrates a flowchart of a method for manufacturing an integrated circuit according to one embodiment.

FIGS. 8A-8B illustrate schematic cross-sectional views illustrating process stages during manufacture of an integrated circuit according to one embodiment.

FIGS. 9A-9C illustrate schematic cross-sectional views illustrating successive process stages during manufacture of an integrated circuit according to one embodiment.

FIGS. 10A-10C illustrate schematic plan views during manufacture of an integrated circuit according to one embodiment.

FIGS. 11A-11M illustrate schematic cross-sectional views illustrating successive process stages during manufacture of an SOI based DRAM memory cell according to one embodiment.

FIG. 12 illustrates a schematic view of an electronic device according to one embodiment.

FIG. 13 illustrates a schematic cross-sectional view of an integrated circuit according to one embodiment.

FIG. 14 illustrates a schematic cross-sectional view according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

In the following, one or more embodiments are described. It should be noted that all embodiments described in the following may be combined in any way, i.e. there is no limitation that certain described embodiments may not be combined with others. Further, it should be noted that some reference signs throughout the Figures denote same or similar elements. The drawings are not necessarily to scale.

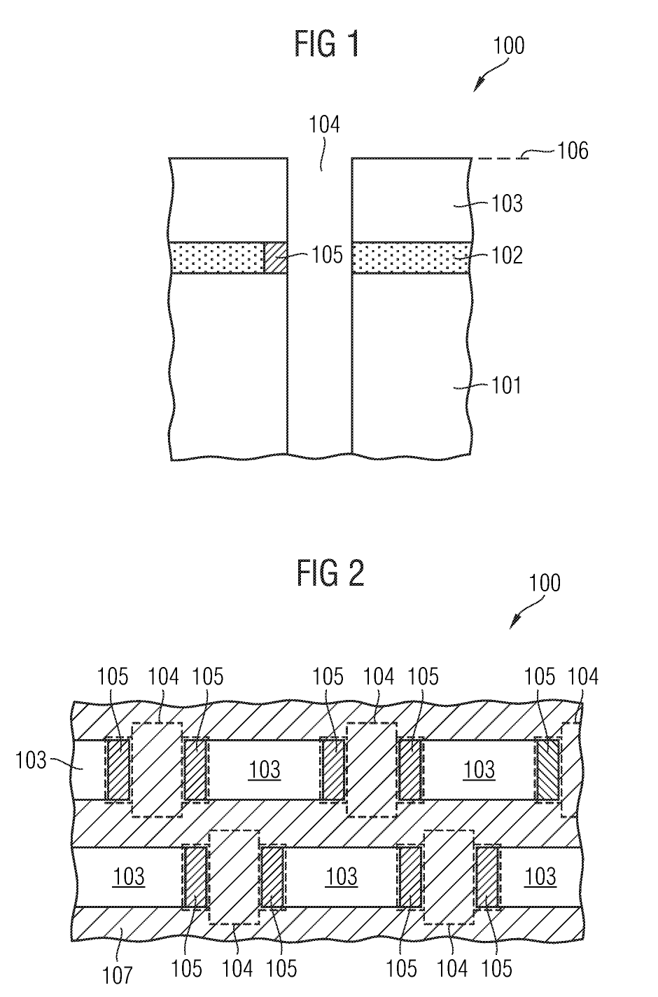

FIG. 1 is a schematic cross-sectional view illustrating an integrated circuit 100 according to one embodiment. The integrated circuit 100 includes a silicon-on-insulator (SOI) carrier including a substrate 101, a buried insulating layer 102 on the substrate 101 and a semiconductor layer 103 on the buried insulating layer 102. A trench 104 penetrates through the semiconductor layer 103, the buried insulating layer 102 and into the substrate 101. A conductive region 105 is formed in the buried insulating layer 102, wherein the conductive region 105 partly surrounds the trench 104 and is configured to interconnect the semiconductor layer 103 and the substrate 101.

It is to be noted that the simplified cross-sectional view illustrated in FIG. 1 merely constitutes a section of the integrated circuit 100. By way of example, further circuit parts may be realized in other sections of the integrated circuit 100, which are not illustrated in FIG. 1. For instance, a plurality of trenches 104 and conductive regions 105 may be arranged within the SOI carrier in a regular pattern, wherein a location of the conductive regions 105 may differ with regard to selected ones of the trenches 104.

The integrated circuit 100 may include further circuit parts which are not illustrated in the simplified view of FIG. 1. For example, semiconductor regions may be formed within the semiconductor layer 103, e.g., by ion implantation or diffusion. Furthermore, isolation structures may be formed within the semiconductor layer 103, e.g., a shallow trench isolation (STI) or a region of local oxidation of silicon (LOCOS). The semiconductor layer 103 may be a silicon layer. The conductive region 105 may be any conductive material, e.g., a semiconductor or a metal or a combination thereof.

The trench 104 ends within the substrate 101 and does not penetrate through substrate 101 (not illustrated in the section illustrated in FIG. 1). It is to be noted that the trench 104 may be filled with any of insulating and conductive materials or a combination thereof. By way of example, a filling within the trench 104 may form part of a trench capacitor of a DRAM memory cell, e.g., a capacitor dielectric and a capacitor electrode.

The arrangement of the conductive region 105 illustrated in FIG. 1 is to be considered merely as an example, as the conductive region 105 may be positioned in many ways so that it partly surrounds the trench 104. The conductive region 105 may correspond to a self-aligned body contact configured to interconnect the substrate 101 and a body region of a field effect transistor formed in the semiconductor layer 103, for example.

Over a surface 106 of the semiconductor layer 103, a wiring area including one or multiple metal layers may be formed (not illustrated in FIG. 1). Between successive metal layers of the wiring area, intermetal dielectric layers may be formed. An electrical interconnection between different metal layers of the wiring area as well as an electrical connection of a metal layer and semiconductor regions formed within the semiconductor layer 103 may be provided by conductive vias penetrating through the intermetal dielectric layers.

As an example, the integrated circuit 100 may be any of volatile random access memories (volatile RAM) such as static RAM (SRAM) and dynamic random access memories (DRAM), e.g., embedded DRAM (eDRAM), non-volatile memories such as phase change random access memories (PCRAM), magnetic random access memories (MRAM), ferroelectric random access memories (FRAM, FERAM), semiconductor-oxide-nitride-oxide semiconductor memories (SONOS), erasable programmable read-only memories (EPROM), electrically erasable programmable read-only memories (EEPROM) and flash memories, e.g., of NOR or NAND type, for example. Embedded DRAM refers to a capacitor-based dynamic random access memory usually integrated on the same die or chip or in the same package as the main ASIC or processor or logical device, as opposed to external DRAM modules.

Referring to the schematic plan views illustrated in FIGS. 2-4, embodiments of integrated circuits are illustrated showing exemplary arrangements of conductive regions of a plurality of trenches formed in a regular pattern. It is to be noted that FIGS. 2-4 illustrate simplified plan views on a top surface of the semiconductor layer 103, e.g., on surface 106 of FIG. 1. Positions of the trenches 104 and the conductive regions 105 are indicated by dashed lines in FIGS. 2-4, respectively.

Referring to the schematic plan view of FIG. 2, there is illustrated an integrated circuit 100 according to one embodiment. The semiconductor layer 103 is patterned into a plurality of active areas which are electrically isolated from each other by a shallow trench isolation (STI) structure 107. The shallow trench isolation structure 107 may include one or a combination of insulating materials such as oxides, e.g., SiO₂, Al₂O₃, Ta₂O₅, BSG (Boron Silicate Glass), BPSG (Boron Phosphor Silicate Glass), SOG (Spin-On-Glass), and nitrides, e.g., Si₃N₄. These materials may be formed by well-known deposition methods such as CVD (Chemical Vapor Deposition) or plasma CVD processes, for example. The conductive regions 105 partly surround the trenches 104. It is to be noted that the conductive regions 105 are positioned below the semiconductor layer 103 as is illustrated in more detail in the schematic view of FIG. 1. In the configuration illustrated in FIG. 2, the conductive regions 105 are equally arranged with regard to the plurality of trenches 104. Furthermore, these conductive regions 105 are also symmetrically positioned with regard to opposing sidewalls of each of the trenches 104.

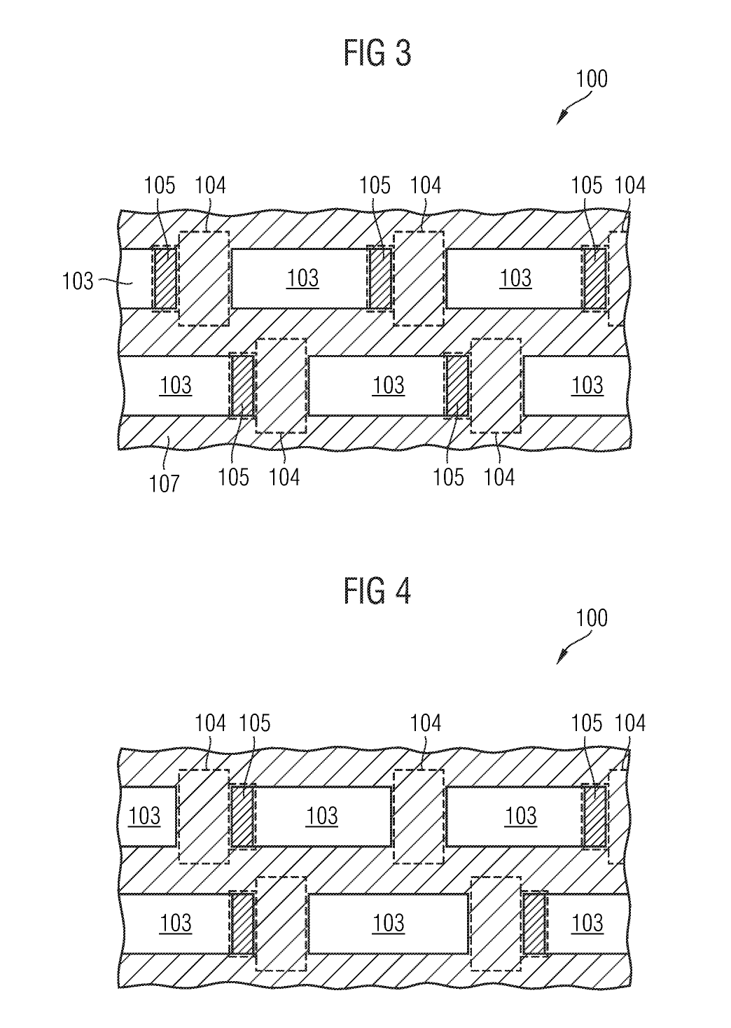

As is illustrated in the simplified plan view of FIG. 3 illustrating an integrated circuit 100 according to a further embodiment, the conductive regions 105 are, similarly to the embodiment illustrated in FIG. 2, partly surrounding the trenches 104. However, contrary to the embodiment illustrated in FIG. 2, these conductive regions 105 are solely arranged adjacent to one of four neighboring sidewalls of each of the trenches 104 and are thus not symmetrically arranged with regard to opposing sidewalls of each of the trenches 104.

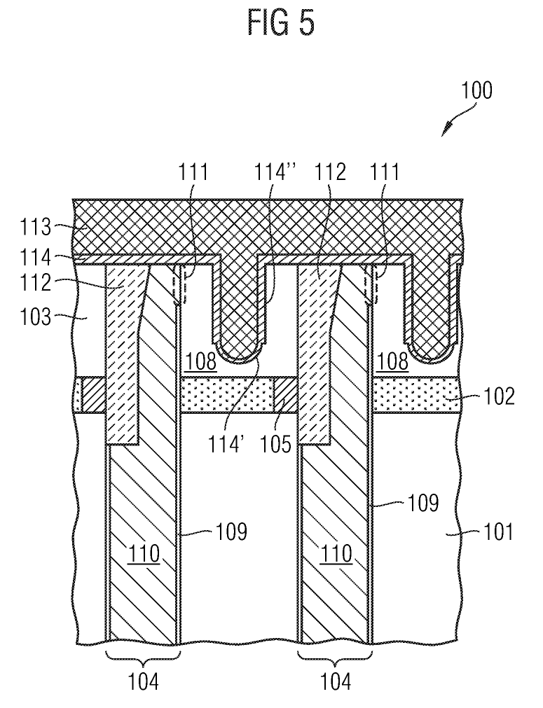

As is illustrated in the simplified plan view of FIG. 4 illustrating an integrated circuit 100 according to yet another embodiment, the conductive regions 105 are, in contrast to the embodiments illustrated in FIGS. 2 and 3, solely equally arranged with regard to selected ones of the trenches 104. Hence, a position of the conductive regions 105 differs with regard to some of the trenches 104, e.g., with regard to the three trenches 104 illustrated in the upper section of the plan view of FIG. 4.

FIG. 5 is a schematic cross-sectional view illustrating an integrated circuit 100 according to a further embodiment. As regards the alignment of the conductive regions 105 with respect to the trenches 104, the integrated circuit 100 is similar to the embodiment illustrated in FIG. 1. However, the embodiment illustrated in FIG. 5 provides further details with regard to the integrated circuit 100, e.g., with regard to a further processing of the semiconductor layer 103 and the trenches 104. The integrated circuit 100 illustrated in FIG. 5 refers to a SOI deep trench DRAM cell concept. Here, the conductive regions 105 define self-aligned body contacts providing an interconnection between the substrate 101 and a body region 108 formed within the semiconductor layer 103. It is to be noted that, for illustration purposes, further semiconductor regions formed within the semiconductor layer 103, e.g., source/drain regions, are omitted.

Within the trenches 104 part of a deep trench capacitor is formed. A deep trench dielectric structure 109 covers part of the sidewalls and a bottom side of the trenches 104 (bottom side not illustrated in the section of FIG. 5). The deep trench dielectric structure 109 may be a single layer or a multilayer stack of dielectric layers that may include materials such as oxides, e.g., SiO₂, nitrides, e.g., Si₃N₄, and high-k dielectrics such as metal oxides, e.g., Al₂O₃, Ta₂O₅, TiO₂, for example. The deep trench dielectric structure 109 constitutes a capacitor dielectric formed between a first capacitor plate defined by the substrate 101 and a second capacitor plate defined by a deep trench electrode 110 within the trenches 104. The deep trench electrode 110 may be of a conductive material, e.g., a doped semiconductor material such as doped polysilicon or a metal.

Furthermore, the SOI DRAM memory cell concept illustrated in FIG. 5 includes a single side buried strap and, at a connection area 111, the deep trench electrode 110 is connected to the semiconductor layer 103, e.g., to a source/drain region of a respective memory cell transistor (drain/source region not illustrated in FIG. 5). In this connection area 111, the deep trench dielectric structure 109 is omitted. An insulating structure 112 fills the trenches 104 in a region not completed by the deep trench electrode 110.

By way of example, the memory transistor of the SOI deep trench DRAM cell illustrated in FIG. 5 is formed as a U-shaped transistor device including an electrode 113 electrically isolated from the semiconductor layer 103 by a further insulating structure 114. The further insulating structure includes gate oxide segments 114′ and spacer segments 114″. It is to be noted that the U-shaped transistor device of the SOI deep trench DRAM memory cell illustrated in FIG. 5 is to be considered merely as an example out of a plurality of appropriate transistor layouts. By way of example, planar MOSFETs (Metal Oxide Semiconductor Field Effect Transistors) or FINFETs may be used.

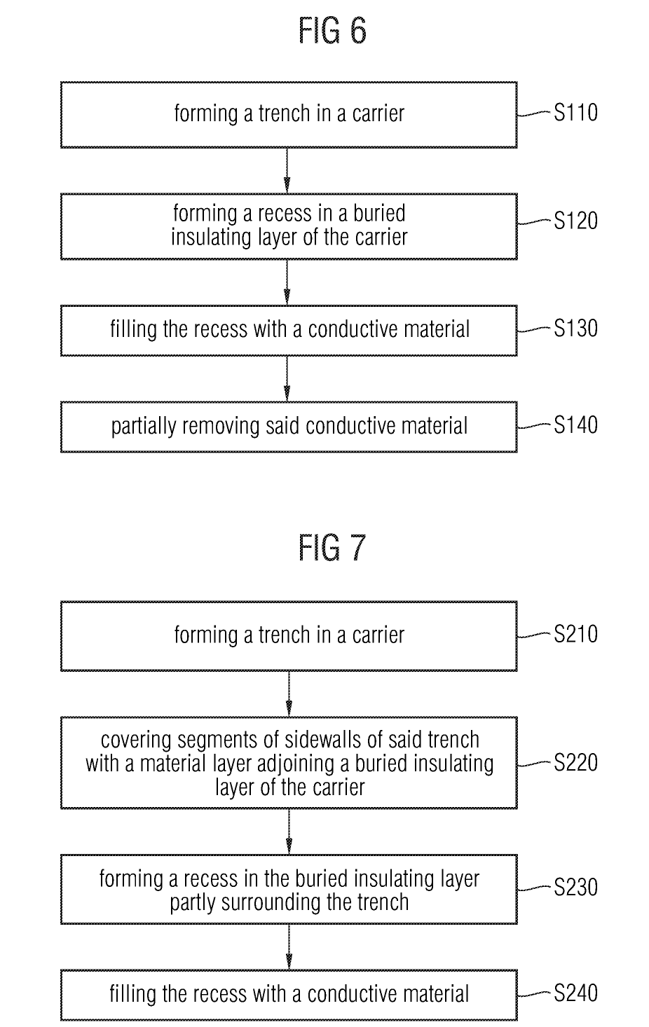

In FIG. 6, a method for manufacturing an integrated circuit according to one embodiment is illustrated using a flowchart. At S110, a trench is formed in a carrier including a substrate, a buried insulating layer on the substrate and a semiconductor layer on the buried insulating layer, the trench extending at least through the semiconductor layer and into the buried insulating layer. Thereafter, at S120, a recess is formed in the buried insulating layer. The formation of this recess starts from an outer sidewall of the trench. At S130, the recess is filled with a conductive material. Thereafter, at S140, the conductive material is partially removed, e.g., by forming a shallow trench isolation structure. Hence, the conductive material partly surrounds the trench.

A further embodiment related to a method for manufacturing an integrated circuit is elucidated with reference to the flowchart illustrated in FIG. 7. At S210, similar to S110 of the embodiment illustrated in FIG. 6, a trench is formed in a carrier including a substrate, a buried insulating layer on the substrate and a semiconductor layer on the buried insulating layer, the trench extending at least through the semiconductor layer and into the buried insulating layer. Thereafter, at S220, segments of sidewalls of the trench are covered with a material layer adjoining the buried insulating layer. At S230, a recess is formed in the buried insulating layer, wherein the recess partly surrounds the trench. Thereafter, at S240, similar to S130, the recess is filled with a conductive material. Hence, the material layer is used as a mask when forming the recess resulting in a recess partly surrounding the trench.

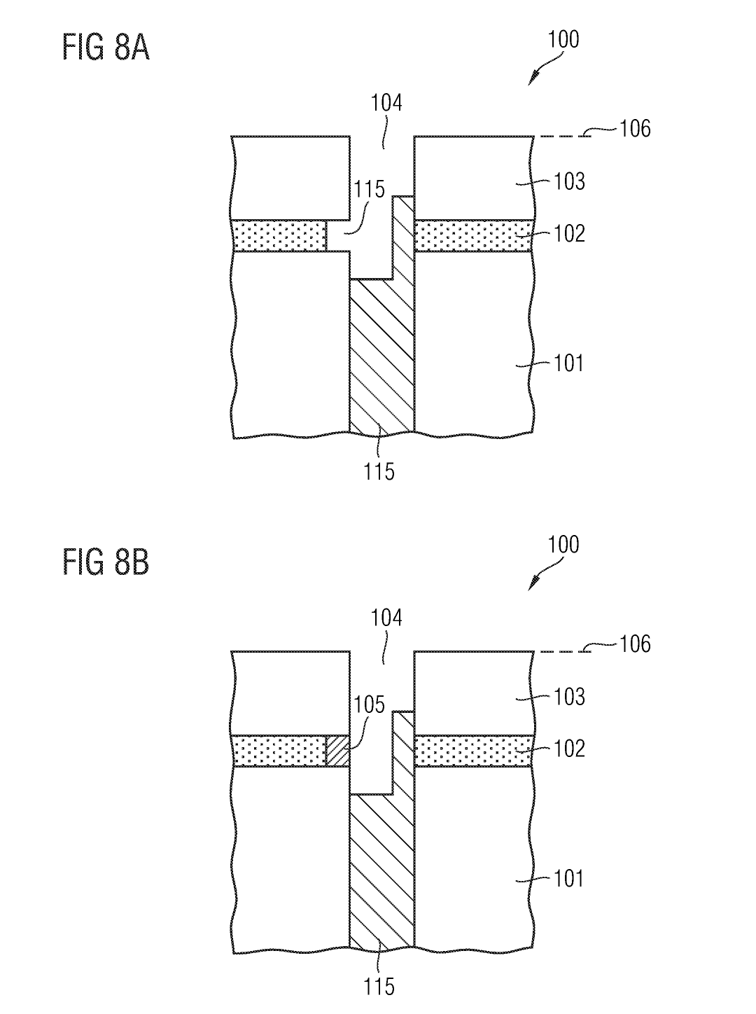

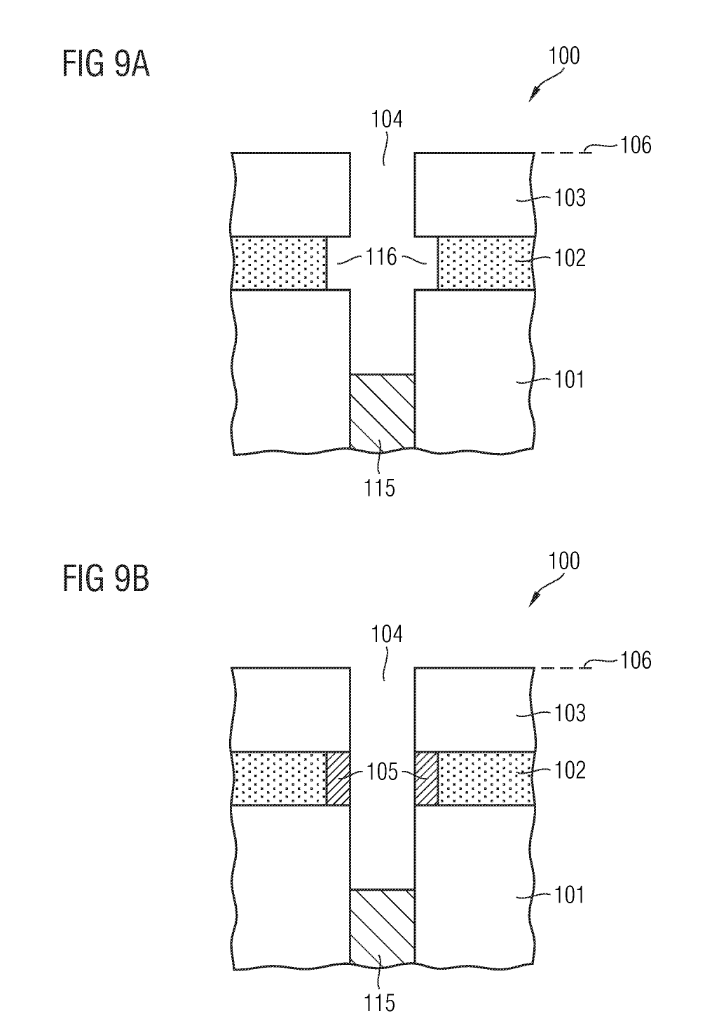

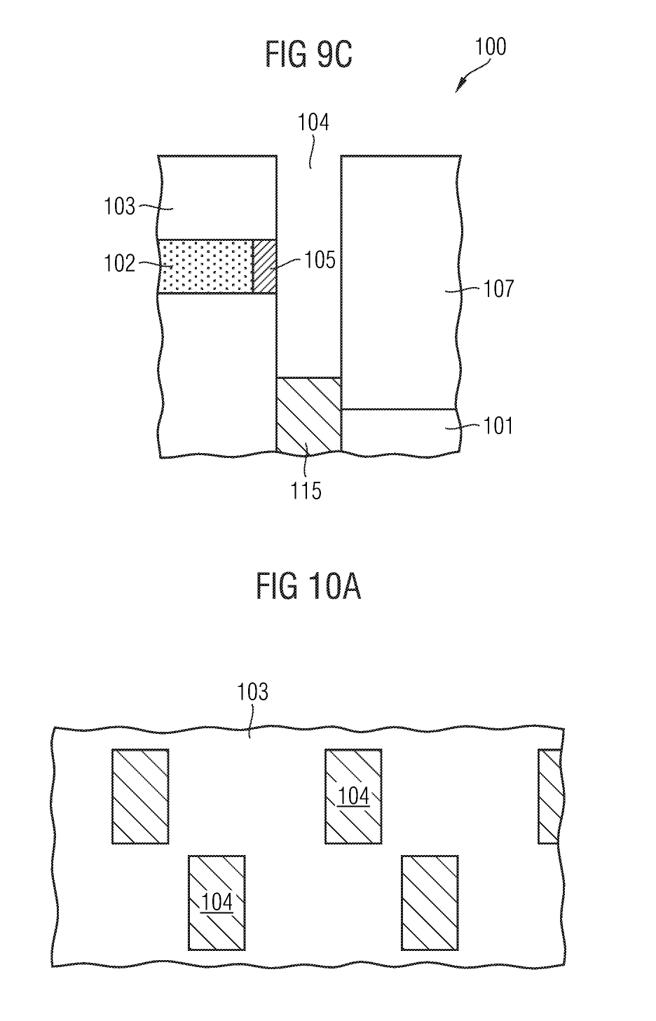

In the following, the methods for manufacturing an integrated circuit elucidated by the flowcharts illustrated in FIGS. 6 and 7 will be illustrated with referenced to schematic cross-sectional views illustrated in FIGS. 8A-8B and 9A-9C, respectively.

FIGS. 8A-8B illustrate schematic cross-sectional views during manufacture of an integrated circuit according to the method elucidated in the flowchart of FIG. 7. After providing a SOI carrier including the substrate 101, the buried insulating layer 102 and the semiconductor layer 103, a trench 104 is formed within the SOI carrier penetrating from a surface 106 of the semiconductor layer 103 into the substrate 101. After providing a material layer 115 covering segments of sidewalls of the trench 104 adjacent to the buried insulating layer 102, a recess 116 is formed in the buried insulating layer 102 starting from an outer sidewall of the trench 104. The recess 116 partly surrounds the trench 104 due to the provision of the material layer 115 serving as a mask during formation of the recess 116. By way of example, the recess 116 may be formed by a selective etch using an etch process that allows to etch the material of the buried insulating layer 102 with a comparable higher etch rate than the materials of the semiconductor layer 103, the substrate 101 and the material layer 115, respectively.

As is illustrated in FIG. 8B, the recess 116 is filled with a conductive material. Hence, the conductive region 105 is provided.

It is to be noted that further processing steps, e.g., affecting the trench 104 of the semiconductor layer 103, may be carried out. These further processing steps are not limited in any way and may be carried out before, after or in between the processing steps illustrated in FIGS. 8A-8B and 9A-9C, respectively. By way of example, a shallow trench isolation structure may be formed in a process stage subsequent to the process stage illustrated in FIG. 8B. This shallow trench isolation structure may be defined such that one of the opposing sidewalls of the conductive region 105 adjoins to the substrate 101 and the other one of opposing sidewalls of the conductive region 105 adjoins to the shallow trench isolation structure. The shallow trench isolation structure may end on a top side of the conductive region 105, for example.

FIGS. 9A-9C illustrate schematic cross-sectional views during manufacture of an integrated circuit 100 according to a method elucidated in the flowchart of FIG. 6. Referring to FIG. 9A, the SOI carrier including layers 101, 102 and 103 is provided. After forming the trench 104 penetrating into the SOI carrier, the material layer 115 is filled in the trench 104 leaving those segments of the sidewalls of the trench uncovered, which adjoin to the buried insulating layer 102. Thereafter, the recess 116 is formed in the buried insulating layer 102. The recess 116 surrounds the buried insulating layer 102 due to the fact that, contrary to the embodiment illustrated in FIG. 8A, the material layer 115 does not, during formation of the recess 116, cover any segments of the sidewalls of the trench 104 that adjoin to the buried insulating layer 102.

As is illustrated in FIG. 9B, the recess 116 is filled with a conductive material. Thereby the conductive region 105 is formed.

As is illustrated in FIG. 9C, when forming the shallow trench isolation structure 107, the semiconductor layer 103, the buried insulating layer 102, the conductive region 105 and the substrate 101 are partly removed, respectively. As a result, the conductive region 105 partly surrounds the trench 104.

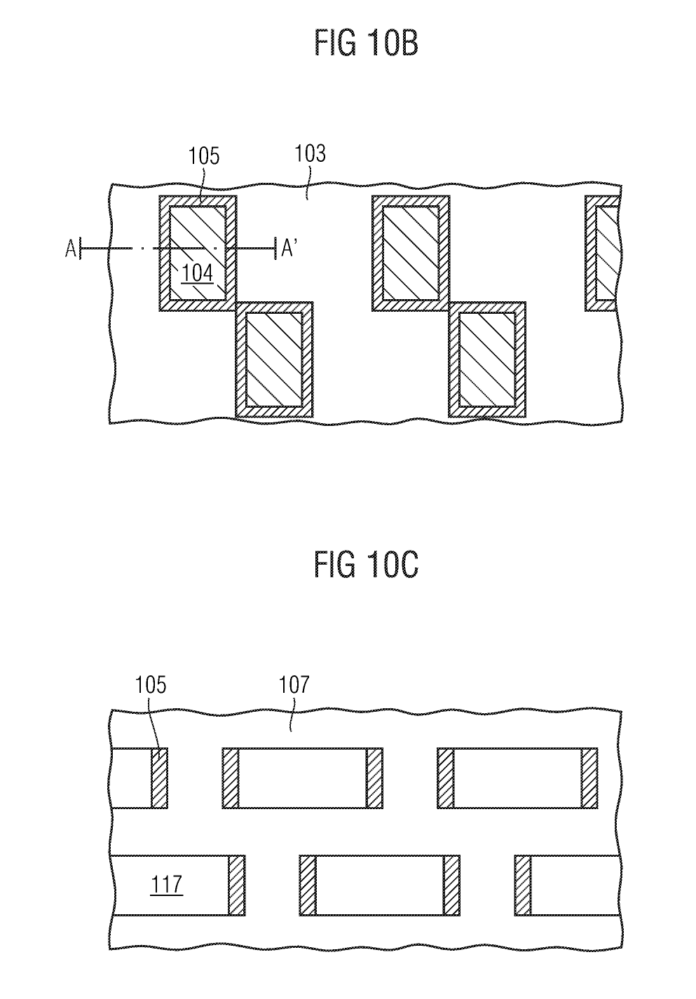

Referring to the schematic plan views illustrated in FIGS. 10A-10C, a method for manufacturing an integrated circuit 100 according to one embodiment will be elucidated. This embodiment is related to the method described in conjunction with the flowchart illustrated in FIG. 6.

As is illustrated in the schematic plan view of FIG. 10A, an SOI carrier is provided. The trenches 104 penetrate into the substrate starting from a surface of a semiconductor layer 103. It is to be noted that the semiconductor layer 103 may be covered by an auxiliary layer such as a pad nitride or a pad oxide layer, for example.

As is illustrated in FIG. 10B, conductive regions 105 are formed surrounding the trenches 104. As regards an exemplary cross-sectional view along a cut line A-A′ of FIG. 10B, reference is taken to FIG. 9B.

After formation of the conductive regions 105, a trench isolation structure 107 is formed, as is illustrated in the schematic plan view of FIG. 10C. The formation of the trench isolation structure 107 allows to segment the semiconductor layer 103 into a plurality of mutually distinctly formed active area regions 117. When forming the shallow trench isolation structure 107, similar to the method feature elucidated with regard to FIG. 9C, part of the semiconductor layer 103, part of the buried insulating layer 102 (not illustrated in FIG. 10C), part of the conductive regions 105 and part of the substrate 101 (not illustrated in FIG. 10C) are removed, respectively. Hence, each of the trenches 104 is partly surrounded by the conductive regions 105.

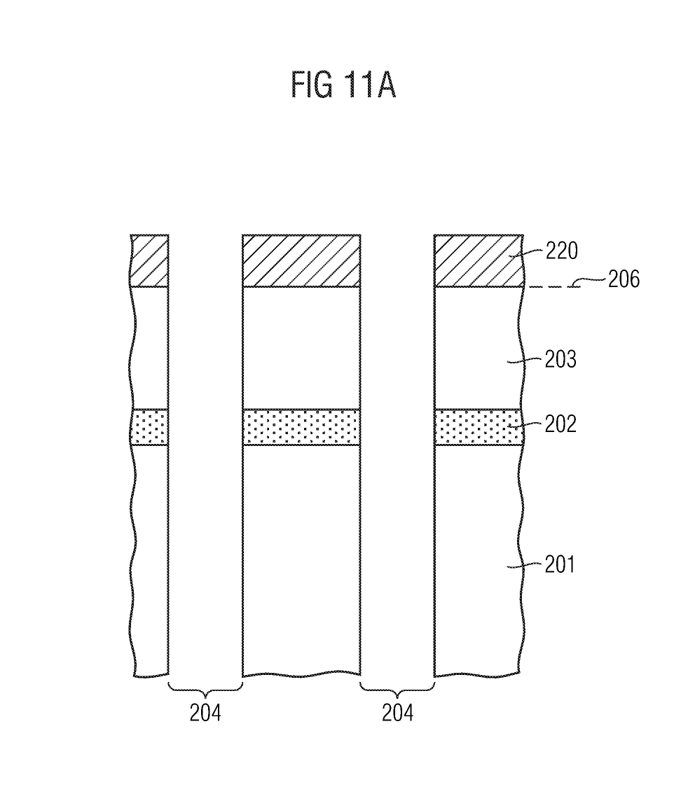

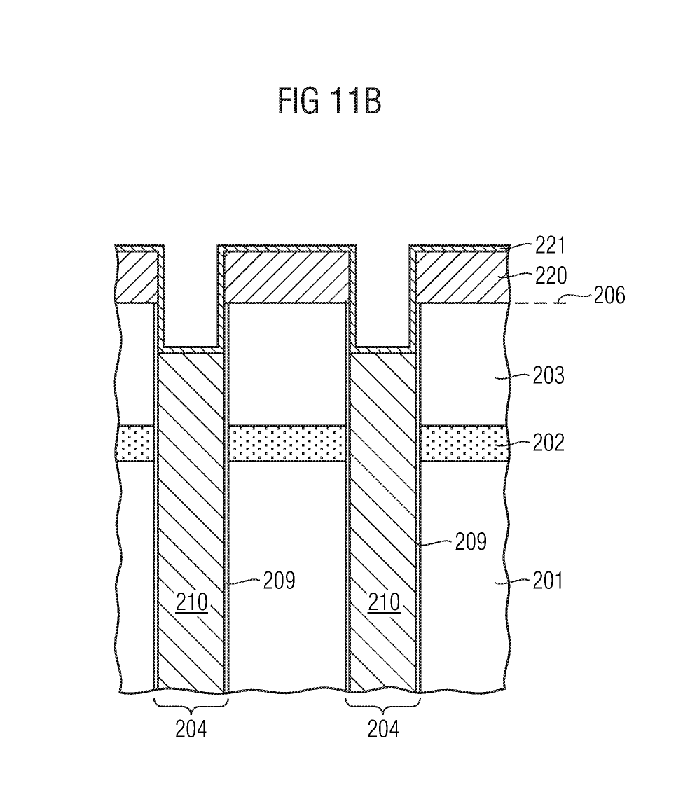

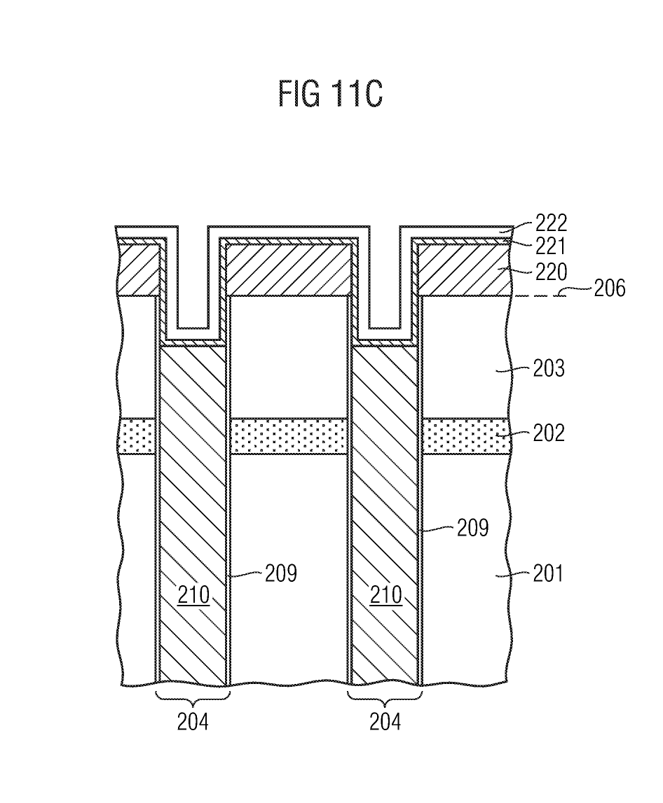

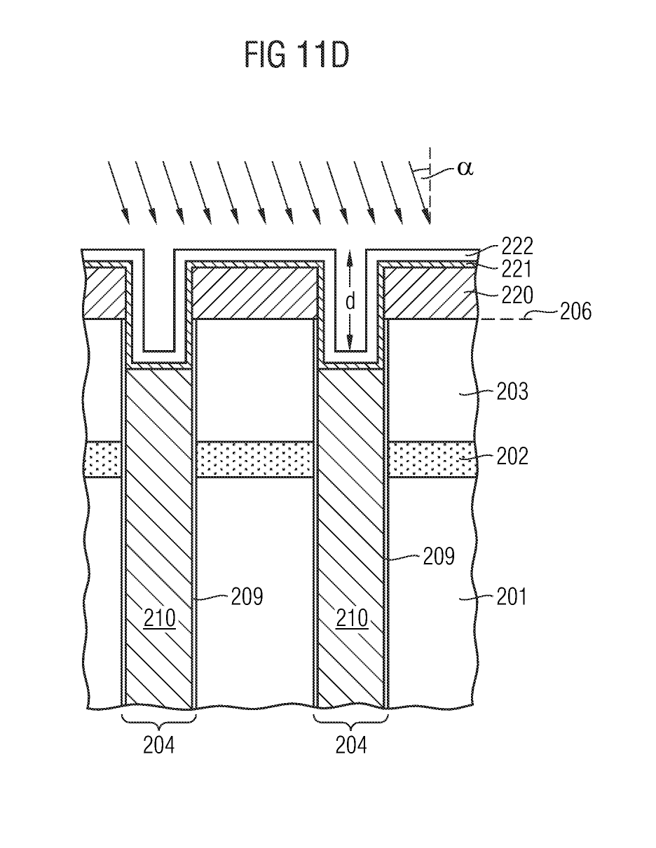

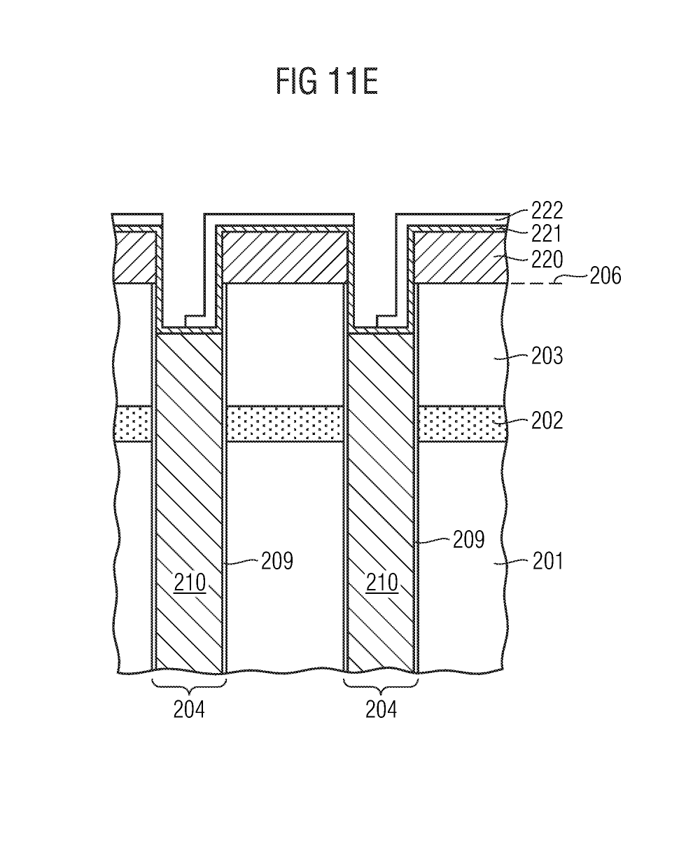

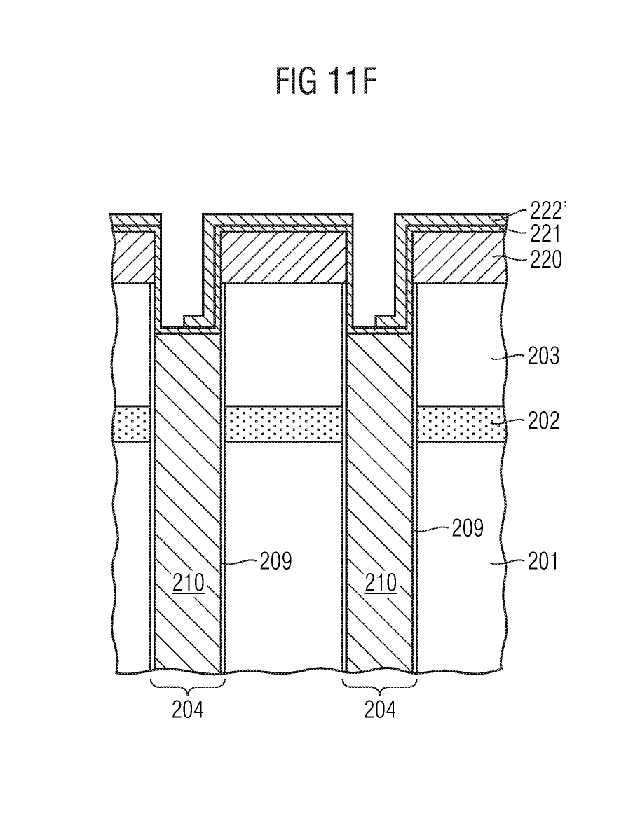

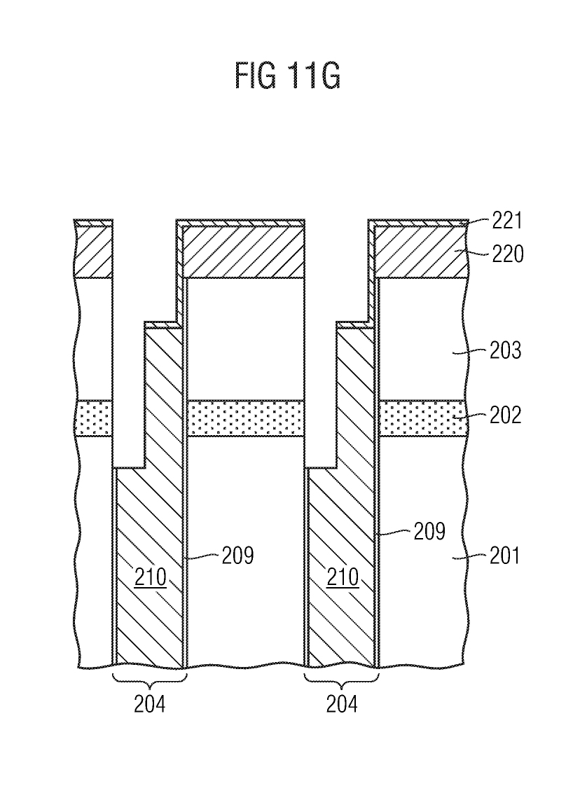

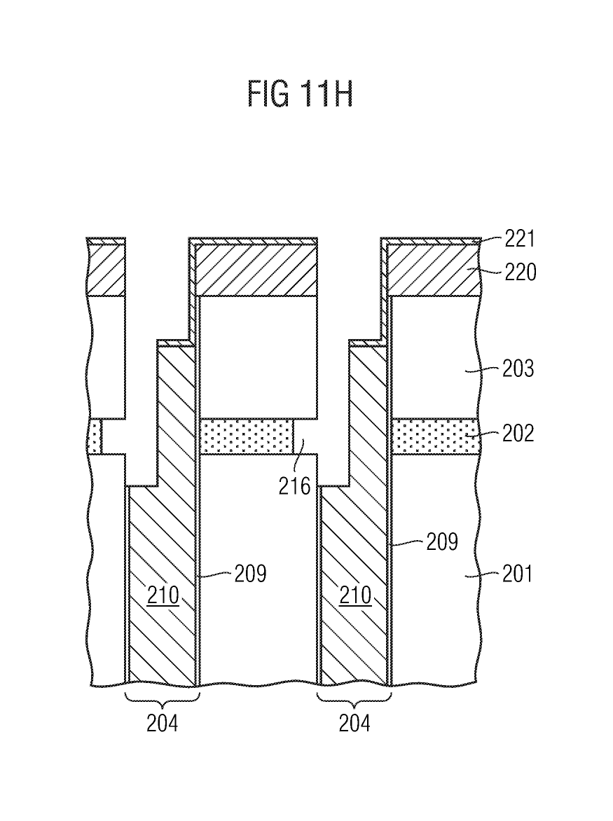

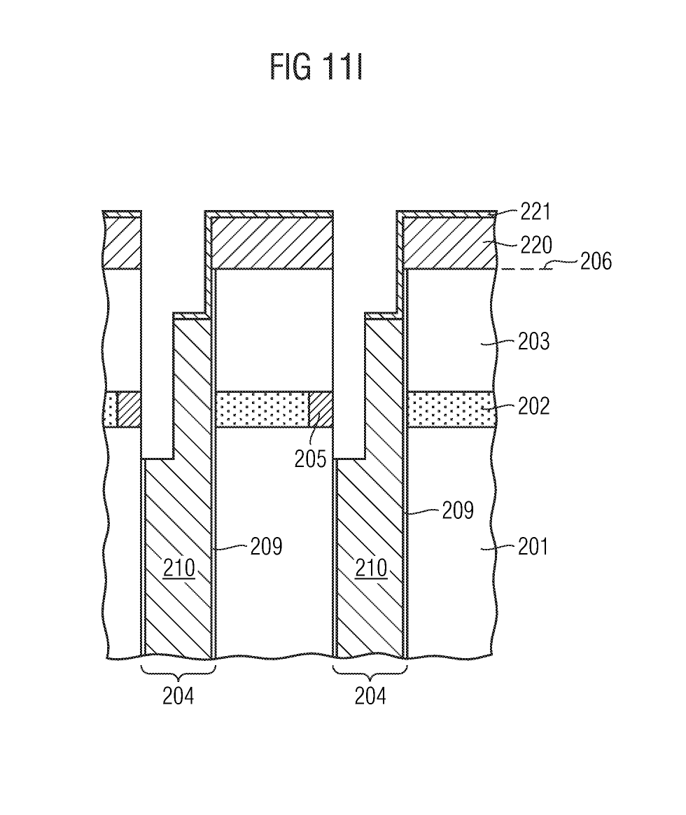

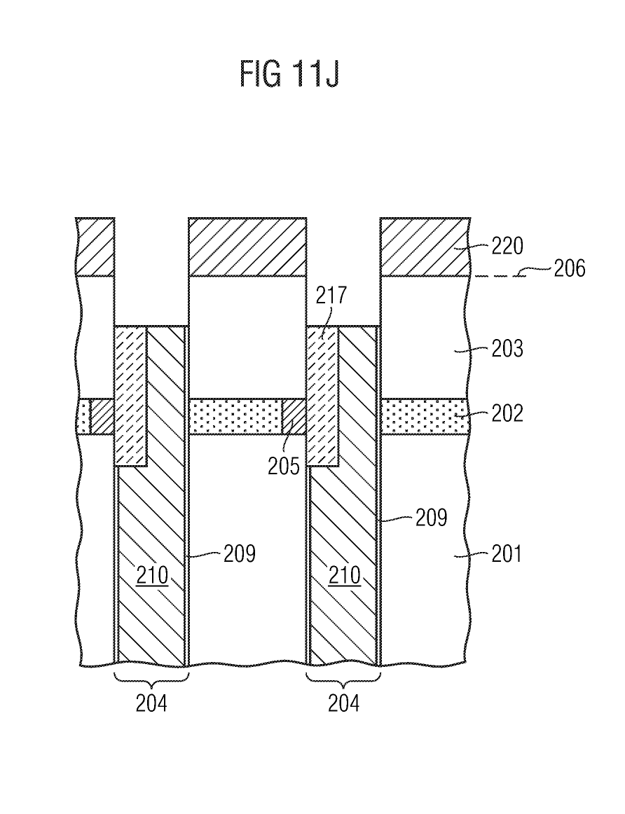

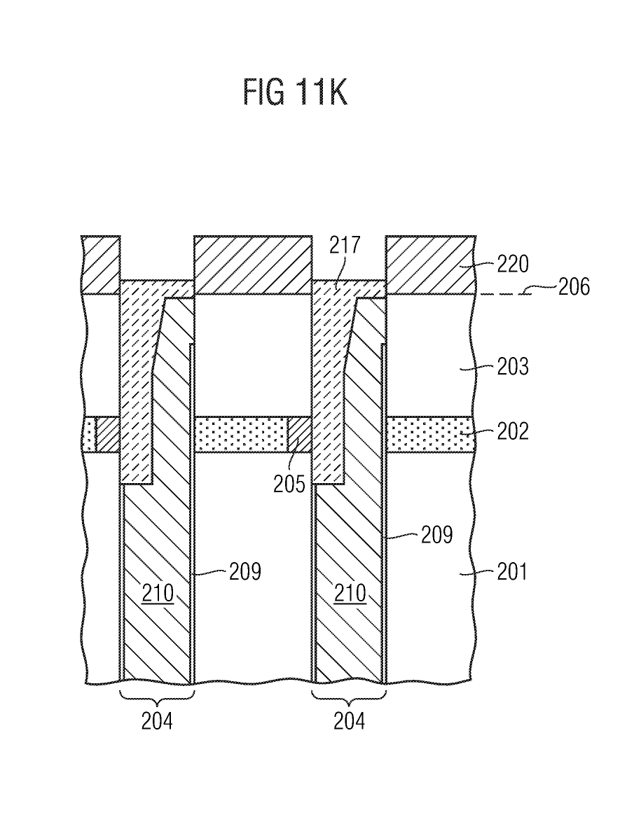

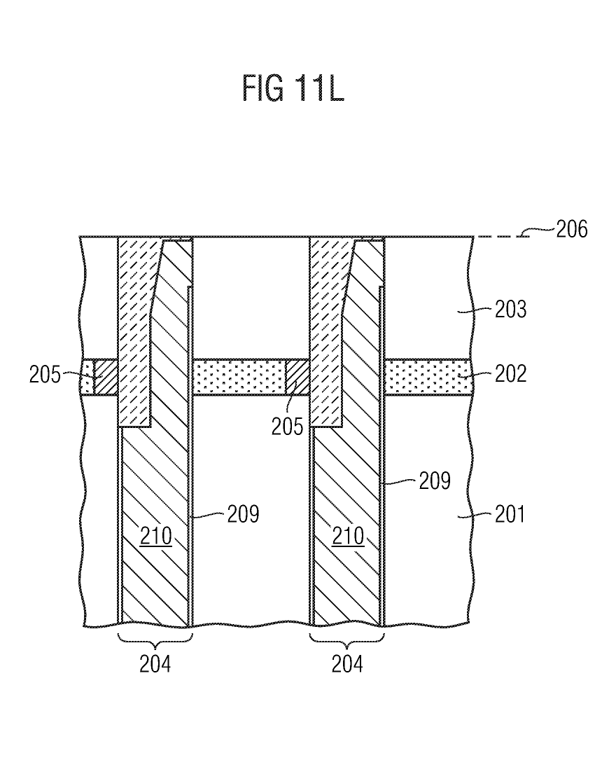

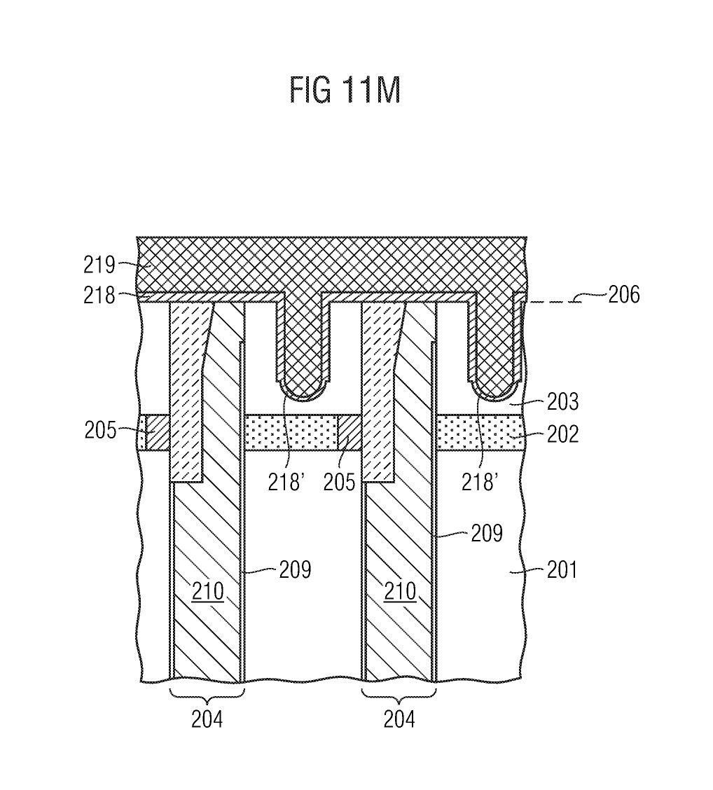

In the following, a method for manufacturing an integrated circuit 200 will be described with reference to a sequence of schematic cross-sectional views elucidating different process stages. The cross-sectional views illustrated in FIG. 11A-11M relate to an SOI deep trench (DT) DRAM cell concept. However, it is to be understood that the manufacturing methods elucidated in the flowcharts illustrated in FIGS. 6, 7 may be integrated into a plurality of process flows for fabricating integrated circuits, e.g., process flows for manufacturing different types of memory cell concepts.

Referring to FIG. 11A illustrating a section of an SOI carrier, there is provided a substrate 201, a buried insulating layer 202 e.g., a buried oxide layer, arranged on the substrate 201, and a semiconductor layer 203 arranged on the buried insulating layer 202, e.g., a silicon layer. Over the semiconductor layer 203 an auxiliary layer or several auxiliary layers, e.g., a pad nitride layer 220, may be provided. By way of example, a material of the auxiliary layer 220 may be chosen in view of its etch selectivity vis-à-vis the materials of the semiconductor layer 203 and the substrate 201, respectively. By way of example, the substrate may be of silicon. However, further materials, e.g., semiconductor materials may be used. From a surface 206 of the semiconductor layer 203, deep trenches 204 are formed penetrating through the semiconductor layer 203, the buried insulating layer 202 and into the substrate 201. It is to be understood that FIGS. 11A-11M merely illustrate a section of the substrate 201 not showing that a bottom side of the trenches 204 ending within the substrate 201.

Turning now to the schematic cross-sectional view of FIG. 11B, multiple process steps will be elucidated. After formation of a deep trench dielectric structure 209 covering a bottom side and sidewalls of the trenches 204, respectively, the trenches 204 are filled with a deep trench electrode 210, which is partly recessed, e.g., by an etch process. By way of example, a material for the deep trench electrode 210 may be chosen as polysilicon. In general, the material of the deep trench electrode may be chosen in view of its conductivity and etch selectivity with regard to selective etch processes integrated in the process flow, for example. After formation of the deep trench electrode 210 an optional liner 221 may be formed on an uncovered surface side including the auxiliary layer 220. By way of example, the liner 221 may be of nitride. It is to be noted that this liner 221 may assist in single-sided buried strap (SSBS)-like processes, but may not be required in further processes.

As is illustrated in FIG. 11C, a further auxiliary layer 222, e.g., a polysilicon layer, is formed on the liner 221. A material of the further auxiliary layer 222 may be chosen such that different etching rates may be achieved by selective ion implantation. By way of example, an etch rate characteristic of a semiconductor material against its doping concentration may be considered. Furthermore, different etching rates may be based on an etch rate characteristic against the crystal structure. In the latter case the crystal structure of the further auxiliary layer 222 may be altered by ion implantation.

As is illustrated in the schematic cross-sectional view of FIG. 11D, a tilted ion implantation is carried out so as to selectively implant ions into the further auxiliary layer 222. By properly choosing an implantation angle α taking into account a depth d from a bottom side of the further auxiliary layer 222 within the trenches 204 up to a top side thereof, ions may be selectively implanted into the further auxiliary layer 222 only with regard to one of two opposing sidewalls of the trenches 204. Furthermore, these ions may be implanted into the further auxiliary layer 222 merely on part, e.g., half, of its bottom side within the trenches 204.

As is illustrated in the schematic cross-sectional view of FIG. 11E, those parts of the further auxiliary layer 222 having no or insufficient ions implanted therein, are removed. By way of example, selective removal of the auxiliary layer 222 may be carried out by etch processes involving etch solutions. An appropriate etch solution may provide different etch rates with regard to differently doped regions of the material constituting the further auxiliary layer 222. As an option, cleaning processes may go ahead or follow. As an example, choosing polysilicon as a material for the further auxiliary layer and selectively implanting BF₂ into this layer, a selective etch may be carried out using an etch chemistry including hyperfluoric acid, e.g., in diluted form, and diluted ammonia.

Referring to the schematic cross-sectional view illustrated in FIG. 11F, a treatment effecting the further auxiliary layer 222 may be carried out in order to convert the further auxiliary layer 222 into an altered auxiliary layer 222′. This treatment may allow to achieve an etch selectivity of the material of the altered auxiliary layer 222′ vis-à-vis the liner 221 and the deep trench electrode 210. By way of example, an oxidation of polysilicon constituting the further auxiliary layer 222 may lead to the altered auxiliary layer 222′ including SiO₂. The altered auxiliary layer 222′ may then provide a mask for selectively etching the liner 221 and the deep trench electrode 210 in unmasked regions of the trenches 204. However, it is to be understood that this treatment changing the further auxiliary layer 222 into the altered auxiliary layer 222′ may be omitted in case the further auxiliary layer 222 may already be used as an etch mask in the following process step.

As is illustrated in the schematic cross-sectional view of FIG. 11G, the liner 221 is removed in regions not covered by the altered auxiliary layer 222′. Furthermore, the deep trench electrode 210 is recessed within the trenches 204 up to a depth below a bottom side of the buried insulating layer 202. It is to be noted that, during the selective etch of the liner 221 and the deep trench electrode 210, a material of the altered auxiliary layer 222′ may hardly, partly or completely be removed due to a finite etch selectivity between this layer and the liner 221 and the deep trench electrode 210, respectively. This etch process may be an anisotropic etch process, for example. When etching the liner 221 and the deep trench electrode 210 as outlined above, part of the deep trench dielectric structure 209 is uncovered. Those uncovered parts of the deep trench dielectric structure 209 may be partly or completely removed during the etch process acting up on the liner 221 and the deep trench electrode 210. However, remainders or all of the uncovered deep trench dielectric structure 209 may be removed during the following process step.

As is illustrated in the schematic cross-sectional view of FIG. 11H, recesses 216 are formed in the buried insulating layer 202, wherein these recesses 216 partly surround the trenches 214. By way of example, these recesses 216 may be formed by an etch process selectively etching a material of the buried insulating layer 216 vis-à-vis the materials of the liner 221, the auxiliary layer 220, the semiconductor layer 203 and the substrate 201, respectively.

As is illustrated in the schematic cross-sectional view of FIG. 11I, a conductive material is filled into the recess 216 resulting in conductive regions 205. By way of example, this material may be polysilicon. However, other conductive or semiconductive materials may be chosen. When filling the recesses 216 with the conductive material, the trenches 204 may also be partly filled. Therefore, the conductive material may be removed from the trenches 204, e.g., by an etch process such as an anisotropic dry etch process. The materials constituting the liner 221 and the conductive regions 205 may be appropriately chosen such that the liner 221 may be used as an etch mask when removing remainders of the conductive material from the trenches 204.

As is illustrated in FIG. 11J, a dielectric material 217 may be filled into the trenches 204 and recessed to provide a plane top surface of the filling within the trenches 204. By way of example, the dielectric material 217 may be an oxide. In addition, the liner 221 may also be removed.

Referring to the schematic cross-sectional view illustrated in FIG. 11K, a common single-sided buried strap process may be carried out for connecting the deep trench electrode 210 to the semiconductor layer 203 via one of two opposing sidewalls of the trenches 204. Hence, an electrical connection between a storage capacitor and an access transistor of a same memory cell may be achieved. As regards the materials that may be used for enhancing the dielectric material 217 and the deep trench electrode 210 within the trenches 204 (compare FIGS. 11J and 11K), the materials constituting the deep trench electrode 210 and the dielectric material 217 in the process stage illustrated in FIG. 11J may be equal or even different from the materials constituting the extension of these regions towards a top side of the trenches, as is illustrated in FIG. 11K.

Referring to the schematic cross-sectional views of FIGS. 11L and 11M, further processing steps may be carried out to proceed with the manufacture of an SOI DRAM memory cell array. As these processing steps are well-known to the skilled person, they will be merely shortly addressed. As is illustrated in FIG. 11L, the further auxiliary layer 220 may be removed. Furthermore, a shallow trench isolation may be formed (not illustrated in FIG. 11L).

As is illustrated in the schematic cross-sectional view of FIG. 11M, further processing steps for defining memory cell transistors may be carried out. By way of example, the transistor device illustrated in FIG. 11M is formed as a U-shape device. However, this device layout is merely to be considered as an example and further transistor layouts such as planar transistors or FinFETs may be used. In the exemplary cross-sectional view of FIG. 11M showing a process stage during memory cell transistor formation, an isolation structure 218 including a gate oxide section 218′ and a spacer section 218″ may be formed. Furthermore, a gate electrode material 219 may be formed on the isolation structure 218. Further processing steps (not illustrated) such as patterning of the gate electrode material 219 may follow to proceed with the completion of the SOI DRAM.

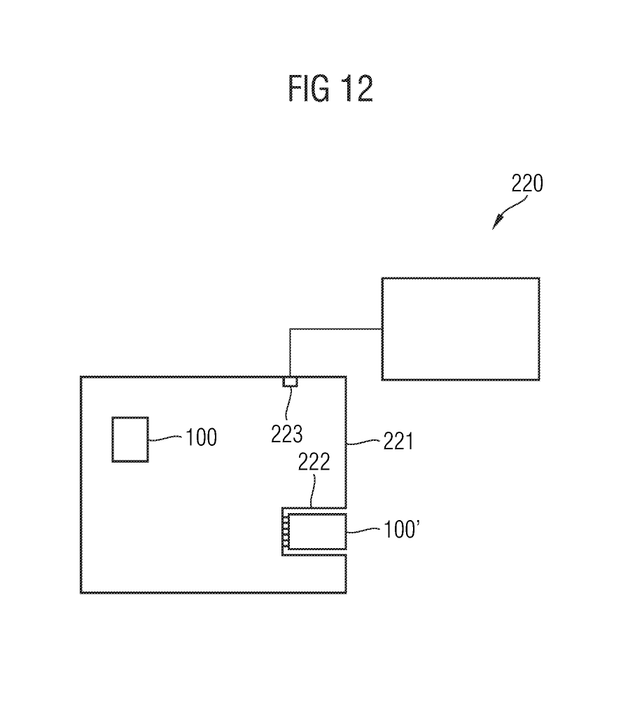

FIG. 12 illustrates a schematic view of an electronic device 220 according to one embodiment. Examples of the electronic device 220 include a computer, for example, a personal computer or a notebook, a server, a router, a game console, for example, a video game console or a portable video console, a graphic card, a personal digital assistant, a digital camera, a cell phone, an audio system, such as any kind of music player or a video system. Nevertheless, as is obvious to the person skilled in the art, the electronic device may be exemplified by any other kind of device in which digital data are processed or transmitted or stored. The electronic device 220 includes an integrated circuit as elucidated in any of the above embodiments. An integrated circuit 100 may be placed within a housing 221 of the electronic device 220. As a further example, the electronic device 220 may include a slot 222 into which an integrated circuit 100′ may be inserted and electrically connected with an interface of the electronic device 220. By way of example, the integrated circuit 100′ may be a memory card. The electronic device 220 may also include further ports or slots such as port 223, e.g., an USB port, which are configured to provide an electrical connection to further electronic devices, e.g., to a display. As is obvious to the person skilled in the art, any other kind of interface between the electronic device 220 and the integrated circuits 100, 100′ may be implemented.

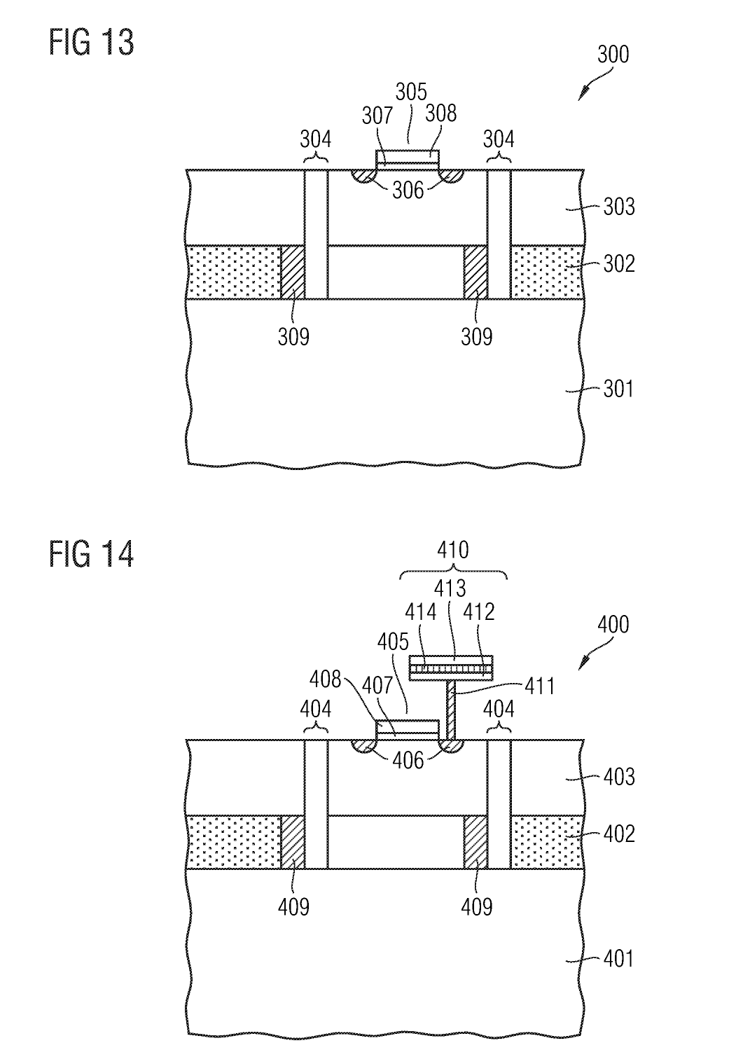

FIG. 13 illustrates a schematic cross-sectional view of an integrated circuit 300 according to one embodiment. The integrated circuit 300 includes a silicon-on-insulator (SOI) carrier with a substrate 301, a buried insulating layer 302 on the substrate 301 and a semiconductor layer 303 on the buried insulating layer 302. A trench 304 penetrates through the semiconductor layer 303 and the buried insulating layer 302 ending on a top side of the substrate 301. It is to be noted that the trench 304 may also partly extend into the substrate 301. The trenches 304 are filled with an insulating structure to provide a trench isolation between neighboring regions of the semiconductor layer 303. The integrated circuit 300 further includes a planar transistor 305. Although transistor 305 is illustrated as a planar transistor, further transistor geometries such as FinFET (Fin Field Effect Transistor), RCAT (Recessed Array Channel Transistor) or Trench MOSFET (Trench Metal Oxide Semiconductor FET) may be used. The transistor 305 includes source/drain regions 306 and a gate structure including a gate dielectric 307 and a gate electrode 308. As can be further gathered from FIG. 13, conductive regions 309 partly surrounding the trenches 304 interconnect the semiconductor layer 303 and the substrate 301. It is to be noted that other devices than transistor 305 may be formed within the semiconductor layer 303. As an example, bipolar transistors, silicon controlled rectifiers, diodes, resistors, capacitors and inductors may be formed within semiconductor layer 303.

FIG. 14 illustrates a schematic cross-sectional view of an integrated circuit 400 according to yet another embodiment. Apart from elements 401-409 corresponding to elements 301-309 elucidated with regard to the embodiment illustrated in FIG. 13, transistor 405 is used as a memory cell transistor of a stacked DRAM memory cell. As is schematically illustrated in FIG. 14 a stacked capacitor 410 is coupled to source/drain region 406 of the transistor 405 via a contact plug 411. The stacked capacitor 410 includes first and second capacitor electrodes 412, 413 separated by a capacitor dielectric 414. The stacked capacitor 410 may be formed of any of conductive and insulating layers provided over semiconductor layer 403.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
a carrier including a substrate, a buried insulating layer on the substrate and a semiconductor layer on the buried insulating layer;
a trench extending at least through the semiconductor layer and into the buried insulating layer; and
a conductive region formed in the buried insulating layer, wherein the conductive region partly surrounds the trench and is configured to interconnect the semiconductor layer and the substrate.

2. The integrated circuit of claim 1, comprising a plurality of the trenches and the conductive regions arranged in a regular pattern.

3. The integrated circuit of claim 2, comprising wherein a location of the conductive region differs with regard to selected ones of the trenches.

4. The integrated circuit of claim 1, comprising wherein the conductive region corresponds to a self-aligned body contact configured to interconnect the substrate and a body region of a field effect transistor formed in the semiconductor layer.

5. The integrated circuit of claim 4, comprising wherein the field effect transistor is a transistor of a DRAM memory cell.

6. The integrated circuit of claim 5, comprising wherein the DRAM memory cell includes a stacked capacitor.

7. The integrated circuit of claim 1, comprising wherein a conductive material is arranged within the trench in at least a trench segment which is laterally adjacent to the substrate.

8. The integrated circuit of claim 7, comprising wherein the trench constitutes part of a trench capacitor of a DRAM memory cell.

9. The integrated circuit of claim 2, further comprising a shallow trench isolation structure, wherein one of the opposing sidewalls of the conductive region adjoins to the substrate and the other one of the opposing sidewalls of the conductive region adjoins to the shallow trench isolation structure.

10. The integrated circuit of claim 2, further comprising a shallow trench isolation structure, wherein one of neighboring two sidewalls of the conductive region adjoins to an outer sidewall of the trench and the other one of the neighboring two sidewalls of the conductive region adjoins to the shallow trench isolation structure.

11. The integrated circuit of claim 1, comprising wherein the trench is filled with an insulating material providing a trench isolation between neighboring regions of the semiconductor layer.

12. An integrated circuit including a transistor, comprising:
a carrier comprising a substrate, a buried insulating layer on the substrate and a semiconductor layer on the buried insulating layer;
a body region of the transistor formed within the semiconductor layer;
a trench extending at least through the semiconductor layer and into the buried insulating layer; and
a self-aligned body contact formed in the buried insulating layer, wherein the self aligned body contact partly surrounds the trench and is configured to interconnect the substrate and the body region.

13. The integrated circuit of claim 12, comprising wherein the transistor constitutes a memory cell transistor.

14. The integrated circuit of claim 12, further comprising a storage capacitor, wherein the transistor and the storage capacitor constitute a memory cell.

15. The integrated circuit of claim 12, comprising wherein the trench is filled with an insulating material providing a trench isolation between neighboring regions of the semiconductor layer.

16. A method for manufacturing an integrated circuit, comprising:
forming a trench in a carrier including a substrate, a buried insulating layer on the substrate and a semiconductor layer on the buried insulating layer, the trench extending at least through the semiconductor layer and into the buried insulating layer to expose a sidewall of the buried insulating layer;
forming a recess in the buried insulating layer from the side wall;
filling the recess with a conductive material; and
partially removing the conductive material.

17. The method of claim 16, comprising partially removing the semiconductor layer, the buried insulating layer, the conductive material and the substrate, respectively, by forming a shallow trench isolation structure.

18. The method of claim 16, comprising extending the shallow trench isolation structure into the substrate.

19. The method of claim 16, comprising covering, when forming the recess, segments of sidewalls of the trench with a material layer adjoining the buried insulating layer.

20. The method of claim 16, comprising wherein the conductive material filled in the recess defines a self-aligned body contact connecting the substrate and forming a body region of a memory array cell transistor in an active area of the semiconductor layer.

21. The method of claim 16, comprising further processing the trench as a trench capacitor of a DRAM memory cell.

22. A method for manufacturing an integrated circuit, comprising:
forming a trench in a carrier including a substrate, a buried insulating layer on the substrate and a semiconductor layer on the buried insulating layer, the trench extending at least through the semiconductor layer and into the buried insulating layer;
covering segments of sidewalls of the trench with a material layer adjoining the buried insulating layer;
forming a recess in the buried insulating layer from an outer sidewall of the trench, wherein the recess partly surrounds the trench; and
filling the recess with a conductive material.

23. The method of claim 22, further comprising:
forming a shallow trench isolation structure, wherein the semiconductor layer, the buried insulating layer, the conductive layer and the substrate are partly removed, respectively.

24. The method of claim 22, further comprising:
forming a shallow trench isolation structure within the semiconductor layer, the shallow trench isolation structure adjoining a surface of the buried insulating layer.

25. The method of claim 22, comprising wherein the conductive material filled in the recess defines a self-aligned body contact connecting the substrate and a body region of a memory array cell transistor formed in an active area of the semiconductor layer.
